(19) United States
(12) Patent Application Publication
(10) Pub. No.: US 2020/0006071 A1
(43) Pub. Date: Jan. 2, 2020

(54) THIN FILM STRUCTURE

(71) Applicant: Chunghwa Picture Tubes, LTD., Taoyuan City (TW)

(72) Inventors: Wen-Jiunn Hsieh, New Taipei City (TW); Chen-Chi Lin, Taoyuan City (TW)

(73) Assignee: Chunghwa Picture Tubes, LTD., Taoyuan City (TW)

(21) Appl. No.: 16/115,576

(22) Filed: Aug. 29, 2018

(30) Foreign Application Priority Data
Jun. 27, 2018 (CN) 201810677661.6

(51) Int. Cl. H01L 21/02; H01L 29/66

(52) U.S. Cl. CPC H01L 21/02672; H01L 29/66765; H01L 21/02532

(57) ABSTRACT

The present invention provides a thin film structure which comprises an amorphous silicon thin film and a plurality of nanoparticles. The plurality of nanoparticles are on a surface of the amorphous silicon thin film, a material of the plurality of nanoparticles includes a photothermal effect material, and therefore, the large-area crystal uniformity of the amorphous silicon thin film during melting and recrystallization can be enhanced.

### CROSS-REFERENCE TO RELATED APPLICATION

This application claims the priority benefit of China application serial no. 201810677661.6, filed on Jun. 27, 2018. The entirety of the above-mentioned patent application is hereby incorporated by reference herein and made a part of this specification.

### BACKGROUND OF THE INVENTION

### 1. Field of the Invention

The present invention relates to a thin film structure, particularly a thin film structure including nanoparticles.

### 2. Description of Related Art

In the current process, preparation methods of crystalline silicon (c-Si) thin films are, for example, low pressure chemical vapor deposition (LPCVD), plasma enhanced chemical vapor deposition (PECVD), solid phase crystallization (SPC), excimer laser crystallization (ELA), rapid thermal annealing (RTA) and metal induced lateral crystallization (MILC). The excimer laser method can be carried out in a low temperature process, and the crystalline silicon thin film produced by the method has large crystal grains, good spatial selectivity, high doping efficiency, few intracrystalline defect, good electrical properties, and electron mobility of up to 400 cm²/volt-second, and thus, is highly favored.

The excimer laser method uses laser pulse waves to heat and melt amorphous silicon, and the amorphous silicon (a-Si) thin film will recrystallize to form the crystalline silicon thin film. However, excimer lasers are generally in the ultraviolet range, the equipment is relatively expensive, and it is difficult to generate large area of irradiation. In addition, the excimer laser method has a problem of poor crystal uniformity for a large-area amorphous silicon thin film.

### SUMMARY OF THE INVENTION

The present invention provides a thin film structure, which can enhance the large-area crystal uniformity of an amorphous silicon thin film during melting and recrystallization.

According to the embodiments of the present invention, the thin film structure comprises an amorphous silicon thin film and a plurality of nanoparticles. The plurality of nanoparticles are on a surface of the amorphous silicon thin film, a material of the plurality of nanoparticles includes a photothermal effect material.

In an embodiment of the present invention, the plurality of nanoparticles are a plurality of rod-shaped nanoparticles, and the extension direction of the plurality of rod-shaped nanoparticles is not perpendicular to the surface of the amorphous silicon thin film.

In an embodiment of the present invention, each of the plurality of rod-shaped nanoparticles comprises a core layer and a dielectric skin layer, the dielectric skin layer wrapping the core layer, and the material of the core layer being different from the material of the dielectric skin layer.

In an embodiment of the present invention, the material of the core layer includes metal, and a material of the dielectric skin layer is selected from one or more of silicon oxide, silicon nitride and silicon oxynitride.

In an embodiment of the present invention, the dielectric skin layer is formed by coating.

In an embodiment of the present invention, the thickness of the dielectric skin layer is between 5 nm and 50 nm.

In an embodiment of the present invention, the percentage of the total cross-sectional area of the plurality of rod-shaped nanoparticles to the surface area of the amorphous silicon thin film is between 30% and 100%.

In an embodiment of the present invention, the material of the plurality of rod-shaped nanoparticles includes silicon or germanium.

In an embodiment of the present invention, the length-to-diameter ratio of the plurality of rod-shaped nanoparticles is between 1.1 and 10.

In an embodiment of the present invention, the coating density of the plurality of rod-shaped nanoparticles on the amorphous silicon thin film is greater than 1.5×10¹³/cm².

In an embodiment of the present invention, the material of the plurality of nanoparticles is selected from one or more of silicon, metal doped silicon, III-V germanium semiconductors, copper sulfide type metal sulfides, carbon nanotubes, graphene type carbon-based materials, iron oxide type magnetic materials, quantum dots and upconversion materials.

In an embodiment of the present invention, the particle size of the plurality of nanoparticles is between 10 nm and 100 nm.

In an embodiment of the present invention, the coating density of the plurality of nanoparticles on the amorphous silicon thin film is between 5/μm² and 100/μm².

In the thin film structure according to the embodiments of the present invention, since the surface of the amorphous silicon film has a plurality of nanoparticles and the material of the plurality of nanoparticles includes the photothermal effect material, the plurality of nanoparticles can be irradiated by light so as to enhance the large-area crystal uniformity of the amorphous silicon thin film during melting and recrystallization.

In order to make the aforementioned and other objectives and advantages of the present invention comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention, together with the description, serve to explain the principles of the invention.

FIG. 1 is a cross-sectional schematic view of a thin film structure according to a first embodiment of the present invention; and

FIG. 2 is a cross-sectional schematic view of a thin film structure according to a second embodiment of the present invention.

### DESCRIPTION OF THE EMBODIMENTS

The embodiments of the present invention will be described in detail below with reference to the accompanying drawings. However, the present invention may be embodied in many different forms and should not be construed as being limited to the embodiments described herein. Rather, these embodiments are disclosed to make the disclosure clear and complete and fully convey the concepts of the present invention to those skilled in the art. The present invention will be limited only by the appended claims. Throughout the specification, the same reference numerals are given to the same components, and the size of some parts will be exaggerated for the clarity of the embodiments of the present invention.

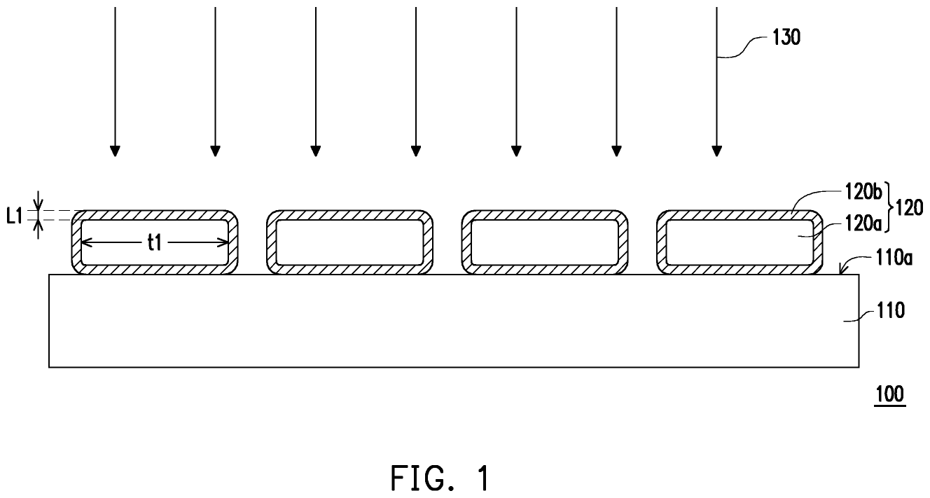

FIG. 1 is a cross-sectional schematic view of a thin film structure according to a first embodiment of the present invention.

Referring to FIG. 1, the thin film structure 100 of the first embodiment comprises an amorphous silicon thin film 110 and a plurality of nanoparticles 120. The plurality of nanoparticles 120 are on a surface 110a of the amorphous silicon thin film 110, a material of the plurality of nanoparticles 120 includes a photothermal effect material.

In some embodiments, the material of the nanoparticles 120 may be selected from one or more of silicon, metal doped silicon, III-V germanium semiconductors, copper sulfide type metal sulfides, carbon nanotubes, graphene type carbon-based materials, iron oxide type magnetic materials, quantum dots (QD) and upconversion materials, but is not limited thereto. A single nanoparticle 120 may be one or more of the above materials. Alternatively, the materials of the various nanoparticles 120 in the plurality of nanoparticles 120 may be the same or different from each other, and are not limited thereto.

In some embodiments, the particle size of the nanoparticles 120 is between 10 nm (nanometers) and 100 nm. At the above-mentioned nanoscale, the physical or chemical properties exhibited by the nanoparticles 120 may be different from a bulk of the same material.

In some embodiments, the length-to-diameter ratio of the nanoparticles 120 is between 0.5 and 10. That is, the nanoparticles 120 may be rod-shaped or granular.

The plurality of nanoparticles 120 of the present invention comprises a photothermal effect material. If a light source (not shown) is provided, light 130 emitted by the light source is irradiated onto the plurality of nanoparticles 120, and the plurality of nanoparticles 120 can convert light energy into heat energy after absorbing the light energy, and then the heat energy is utilized as a phase change energy required when an amorphous silicon thin film is converted into a crystalline silicon thin film. In the above manner, the converted heat energy can be more uniformly transmitted on the amorphous silicon thin film 110, and the large-area crystal uniformity can be enhanced during melting and recrystallization of the amorphous silicon thin film. The light 130 emitted by the light source is, for example, infrared light having a wavelength between 700 nm and 1400 nm, and the light source may be a laser, a xenon lamp, a mercury lamp, a halogen lamp or array type light emitting diodes. In some embodiments, the use of the array type light emitting diodes as the light source can further reduce the process equipment cost, but the present invention is not limited thereto.

Still referring to FIG. 1, in the present embodiment, the nanoparticles 120 are rod-shaped, but the present invention is not limited thereto. In other embodiments, the shape of the nanoparticles may be granular, spherical or ellipsoidal. The extension direction of the plurality of rod-shaped nanoparticles 120 (the long-axis direction of the rod shape) is not perpendicular to the surface 110a of the amorphous silicon thin film 110. When the extension direction of the rod-shaped nanoparticles 120 is not perpendicular to the surface 110a of the amorphous silicon thin film 110, the rod-shaped nanoparticles 120 may have more irradiated area, and thus may have better photothermal conversion efficiency, thereby further enhancing the light utilization ratio of the light 130 emitted by the light source.

In the present embodiment, the extension direction of the plurality of rod-shaped nanoparticles 120 is parallel to the surface 110a of the amorphous silicon thin film 110. Of course, if a portion of the plurality of rod-shaped nanoparticles 120 are irregularly stacked on the surface 110a of the amorphous silicon thin film 110, the extension direction of the irregularly stacked rod-shaped nanoparticles 120 may be slightly not parallel to the surface 110a of the amorphous silicon thin film 110. In addition, the surface 110a of the amorphous silicon thin film 110 formed by deposition may have partial pits or bulges, and if a portion of the plurality of rod-shaped nanoparticles 120 happen to be on the pits or bulges on the surface 110a of the amorphous silicon thin film 110, the extension direction of the rod-shaped nanoparticles 120 on the pits or bulges of the surface 110a of the amorphous silicon thin film 110 may be slightly not parallel to the surface 110a of the amorphous silicon thin film 110. The above-mentioned conditions should still belong to the equal range that “the extension direction of the plurality of rod-shaped nanoparticles 120 is parallel to the surface 110a of the amorphous silicon thin film 110” in the present disclosure.

In some embodiments, the length-to-diameter ratio of the plurality of rod-shaped nanoparticles 120 may be between 1.1 and 10, and the length-to-diameter ratio is a ratio of the length t1 of the core layer 120a to the diameter of the core layer 120a. The coating density of the plurality of rod-shaped nanoparticles 120 on the amorphous silicon thin film 110 is, for example, greater than 1.5×10³/cm².

In the present embodiment, each of the plurality of rod-shaped nanoparticles may comprise a core layer 120a and a dielectric skin layer 120b, the dielectric skin layer 120b completely wrapping the external surface of the core layer 120a, and the melting point of the dielectric skin layer 120b is greater than the melting point of the nanoparticles 120. In other words, a portion of the dielectric skin layer 120b may be located between the core layer 120a and the amorphous silicon thin film 110 such that the core layer 120a is not in direct contact with the amorphous silicon thin film 110. The material of the core layer 120a may be metal; and the material of the dielectric skin layer 120b may be selected from silicide, and the silicide may be one or more of silicon oxide, silicon nitride and silicon oxynitride. When the photothermal effect occurs, the ambient temperature around the nanoparticles 120 can be raised. If the material of the nanoparticle is composed only of a material (such as gold) having a low melting point (i.e., lower than the conversion temperature at which amorphous silicon recrystallizes to form crystalline silicon), the nanoparticles 120 may be melted and combined into granules larger than the nanoparticles 120 in the particle size or a bulk, thus reducing the photothermal effect and even causing the failure of the photothermal effect. Therefore, the risk that the core layers 120a are integrated with each other due to a temperature increase can be reduced by completing wrapping the core layer 120a with the dielectric skin layer 120b, so that the photothermal effect can be performed continuously. In addition, it is more noteworthy that at the nanoscale, the physical or chemical properties of various materials may be different from those of the bulk of the same material. For example, the melting point of a gold bulk is approximately 1063° C., while the melting point of the gold nanoparticles may be lowered to 300° C. to 700° C. according to the their nanoscale. For another example, the melting point of a silver bulk is approximately 962° C., while the melting point of the silver nanoparticles may be even lowered to 100° C. according to the their nanoscale. Therefore, in some embodiments, when the material of the core layer 120a is metal (such as, gold or silver), no metal pollution is generated on the amorphous silicon thin film 110 by wrapping the core layer 120a with the dielectric skin layer 120b, thereby reducing the process steps and enhancing the production efficiency.

In some embodiments, the dielectric skin layer 120b may be formed by a coating process, so that the dielectric skin layer 120b may completely wrap the external surface of the core layer 120a. For example, when the material of the dielectric skin layer 120b is silicon oxide, a hydrolytic condensation reaction may be performed by using tetraethoxysilane (TEOS), a suspension is formed with the core layer 120a material, and then the suspension is coated on the surface of the amorphous silicon thin film 110, but the present invention is not limited thereto. In some embodiments, the thickness L1 of the dielectric skin layer 120b may be between 5 nm and 50 nm. If the thickness L1 of the dielectric skin layer 120b is less than 5 nm, the possibility of damage or deformation of the dielectric skin layer 120b will be increased. If the thickness L1 of the dielectric skin layer 120b is greater than 50 nm, the thermal conductivity may be reduced during the photothermal effect. In a better embodiment of the present invention, when the thickness L1 of the dielectric skin layer 120b is greater than or equal to 20 nm and less than or equal to 50 nm, it is easier for the manufacturing process of the dielectric skin layer 120b (i.e., possibly having a favorable process window), the possibility of damage or deformation of the dielectric skin layer 120b may be well reduced to prevent the core layers 120a from being integrated with each other or melted into nanoparticles due to a temperature increase, and the thermal conductivity is good during the photothermal effect. The percentage of the total cross-sectional area of the plurality of rod-shaped nanoparticles 120 to the surface area of the amorphous silicon thin film 110 may be between 30% and 100%, but the present invention is not limited thereto.

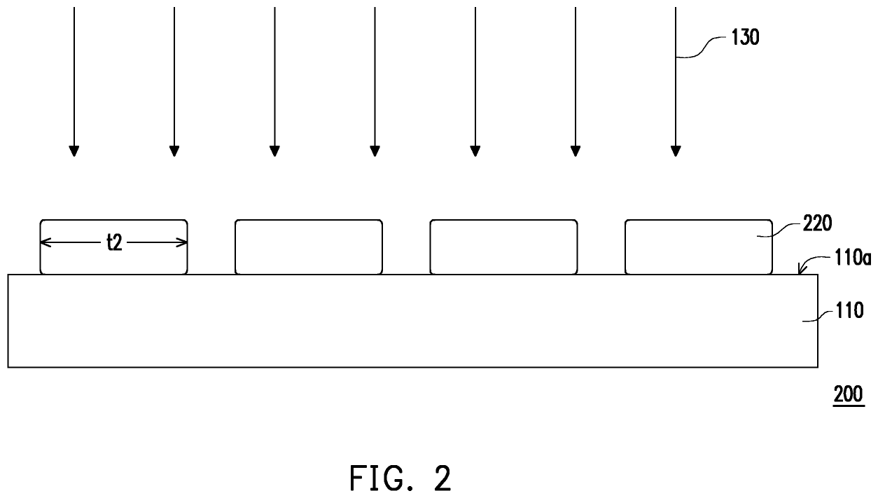

FIG. 2 is a cross-sectional schematic view of a thin film structure according to a second embodiment of the present invention.

Referring to FIG. 2, the difference between a thin film structure 200 of the second embodiment and a thin film structure 100 of the first embodiment lies in that the material of the nanoparticles 220 is silicon or germanium. Specifically, the nanoparticles 220 are of a single-layer structure. The melting temperature of the silicon or germanium nano material is much greater than the temperature generated in the photothermal effect, or greater than the conversion temperature at which the amorphous silicon recrystallizes to form crystalline silicon. For example, the melting temperature of the silicon nano material is 1327° C. Therefore, when the material of the nanoparticles 220 is silicon or germanium, the deformation of the nanoparticles 220 caused by heat may be easily prevented. Besides, in some embodiments, when the material of the nanoparticles 220 is a silicon nano material, the silicon nano material has a function of crystallized seeds, and therefore, the crystallization time can be shortened so as to enhance the productivity, but the present invention is not limited thereto.

In some embodiments, the particle size of the plurality of nanoparticles 220 may be between 10 nm (nanometers) and 100 nm, and the length-to-diameter ratio of the nanoparticles 220 is between 1.1 and 10. That is, the nanoparticles 220 may be rod-shaped or granular. In addition, the above-mentioned length-to-diameter ratio is a ratio of the length t2 of the nanoparticles 220 to the diameter of the nanoparticles 220.

In the present embodiment, the nanoparticles 220 are rod-shaped, and the coating density of the rod-shaped nanoparticles 220 on the amorphous silicon thin film 110 is, for example, greater than 1.5×10¹³/cm².

In other embodiments, if the material of the nanoparticles is silicon or germanium, the nanoparticles may be granular, and the coating density of the granular nanoparticles on the amorphous silicon thin film 110 is, for example, between 5/μm² and 100/μm².

According to the above disclosure, in the thin film structure of the present invention, since the surface of the amorphous silicon thin film has a plurality of nanoparticles and the material of the plurality of nanoparticles includes the photothermal effect, the plurality of nanoparticles can be irradiated by light so as to enhance the large-area crystal uniformity of the amorphous silicon thin film during melting and recrystallization.

Finally, it should be noted that the above embodiments are only used to illustrate the technical solutions of the present invention, and are not limited thereto. Although the present invention has been described in detail with reference to the foregoing embodiments, a person of ordinary skill in the art should understand that the technical solutions described in the foregoing embodiments can be modified or equivalently substituted for some or all of the technical features. These modifications and substitutions do not depart from the scope of the technical solutions of the embodiments of the present invention.

What is claimed is:

1. A thin film structure, comprising:
an amorphous silicon thin film; and
a plurality of nanoparticles on a surface of the amorphous silicon thin film, a material of the plurality of nanoparticles including a photothermal effect material.

2. The thin film structure according to claim 1, wherein the plurality of nanoparticles are a plurality of rod-shaped nanoparticles, and the extension direction of the plurality of rod-shaped nanoparticles is not perpendicular to the surface of the amorphous silicon thin film.

3. The thin film structure according to claim 2, wherein each of the plurality of rod-shaped nanoparticles comprises a core layer and a dielectric skin layer, the dielectric skin layer wrapping the core layer, and a material of the core layer being different from a material of the dielectric skin layer.

4. The thin film structure according to claim 3, wherein a portion of the dielectric skin layer is located between the core layer and the amorphous silicon thin film.

5. The thin film structure according to claim 3, wherein a material of the core layer includes metal, and a material of the dielectric skin layer is selected from one or more of silicon oxide, silicon nitride and silicon oxynitride.

6. The thin film structure according to claim 3, wherein the dielectric skin layer is formed by coating.

7. The thin film structure according to claim 3, wherein
the thickness of the dielectric skin layer is between 5 nm and 50 nm; or
the ratio of the total cross-sectional area of the plurality of rod-shaped nanoparticles to the surface area of the amorphous silicon thin film is between 30% and 100%.

8. The thin film structure according to claim 2, wherein the material of the plurality of rod-shaped nanoparticles includes silicon or germanium.

9. The thin film structure according to claim 2, wherein
the length-to-diameter ratio of the plurality of rod-shaped nanoparticles is between 1.1 and 10; or
the coating density of the plurality of rod-shaped nanoparticles on the amorphous silicon thin film is greater than 1.5×10¹³/cm².

10. The thin film structure according to claim 9, wherein each of the plurality of rod-shaped nanoparticles comprises a core layer and a dielectric skin layer, the dielectric skin layer wrapping the core layer, and a material of the core layer being different from a material of the dielectric skin layer.

11. The thin film structure according to claim 10, wherein a portion of the dielectric skin layer is located between the core layer and the amorphous silicon thin film.

12. The thin film structure according to claim 10, wherein a material of the core layer includes metal, and a material of the dielectric skin layer is selected from one or more of silicon oxide, silicon nitride and silicon oxynitride.

13. The thin film structure according to claim 10, wherein the dielectric skin layer is formed by coating.

14. The thin film structure according to claim 10, wherein the thickness of the dielectric skin layer is between 5 nm and 50 nm.

15. The thin film structure according to claim 14, wherein the thickness of the dielectric skin layer is between 20 nm and 50 nm.

16. The thin film structure according to claim 10, wherein the ratio of the total cross-sectional area of the plurality of rod-shaped nanoparticles to the surface area of the amorphous silicon thin film is between 30% and 100%.

17. The thin film structure according to claim 9, wherein the material of the plurality of rod-shaped nanoparticles includes silicon or germanium.

18. The thin film structure according to claim 1, wherein the material of the plurality of nanoparticles is selected from one or more of silicon, metal doped silicon, III-V germanium semiconductors, copper sulfide type metal sulfides, carbon nanotubes, graphene type carbon-based materials, iron oxide type magnetic materials, quantum dots and upconversion materials.

19. The thin film structure according to claim 18, wherein the particle size of the plurality of nanoparticles is between 10 nm and 100 nm.

20. The thin film structure according to claim 18, wherein the coating density of the plurality of nanoparticles on the amorphous silicon thin film is between 5/μm² and 100/μm².
